(19) United States
(12) Patent Application Publication
(10) Pub. No.: US 2024/0349578 A1
(43) Pub. Date: Oct. 17, 2024

(54) LIGHT-EMITTING SUBSTRATE AND DISPLAY DEVICE

(71) Applicant: Wuhan China Star Optoelectronics Semiconductor Display Technology Co., Ltd., Wuhan, Hubei (CN)

(72) Inventor: Jie PAN, Wuhan, Hubei (CN)

(73) Assignee: Wuhan China Star Optoelectronics Semiconductor Display Technology Co., Ltd., Wuhan, Hubei (CN)

(21) Appl. No.: 17/615,175

(22) PCT Filed: Nov. 24, 2021
(86) PCT No.: PCT/CN2021/132776

§ 371 Date: Jun. 26, 2024

(30) Foreign Application Priority Data
Oct. 28, 2021 (CN) 202111262533.3

(51) Int. Cl. H10K 59/80; H10K 59/122

(52) U.S. Cl. CPC H10K 59/879; H10K 59/122; H10K 59/873

(57) ABSTRACT

The present application provides a light-emitting substrate and a display device, which includes: a substrate; a pixel definition layer disposed on the substrate and comprising a plurality of first openings and a plurality of first dams, and sidewalls of the plurality of first dams enclosing the plurality of first openings; a plurality of light-emitting elements located in the first openings and disposed on the substrate; and a light transmitting layer, wherein at least a portion of the light transmitting layer is filled in the plurality of first openings and covering the plurality of light-emitting elements; a refractive index of the light transmitting layer is greater than a refractive index of the plurality of first dams.

### TECHNICAL FIELD

The present disclosure relates to a field of display technology, in particular, to a light-emitting substrate and a display device.

### BACKGROUND

With development of display technologies, traditional liquid crystal display technologies cannot meet needs of the market gradually in aspects of color rendering, luminous efficiency, flexibility, etc. A new generation of illumination and display technology has become focused issues in investment and research. Wherein, a pixel size composed of micro light-emitting diodes (micro-Led) is relatively small and is suitable for indoor screen and small display applications. However, the smaller a size of the micro light-emitting diode, the larger a proportion of a side emission of the micro light-emitting diode to a total emission. However, at present, a front emission is usually used, and a utilization rate of the side emission is low, causing it to not have high performance advantages.

Therefore, it is necessary to propose a technical solution to solve a problem that a total proportion of the side emission of the micro light-emitting diode is high, resulting in a low light extraction efficiency of a display surface.

### SUMMARY OF THE DISCLOSURE

### Technical Problem

The present disclosure aims to provide a light-emitting substrate and a display device, in order to increase a light extraction efficiency of a light-emitting element on a light-emitting surface of the light-emitting substrate.

### Solutions to the Problem

### Technical Solutions

A light-emitting substrate, comprising:
a substrate;
a pixel definition layer disposed on the substrate and comprising a plurality of first openings and a plurality of first dams, wherein sidewalls of the plurality of first dams enclose for forming the plurality of first openings;
a plurality of light-emitting elements located in the first openings and disposed on the substrate; and
a light transmitting layer, wherein at least a portion of the light transmitting layer fills the plurality of first openings and covers the plurality of light-emitting elements;
wherein a refractive index of the light transmitting layer is greater than a refractive index of the plurality of first dams.

In some embodiments, the light-emitting substrate further comprises: a barrier layer located on a side of the light transmitting layer away from the substrate, wherein the barrier layer comprises a plurality of second openings and a plurality of second dams, sidewalls of the plurality of second dams enclose for forming the plurality of second openings, the second openings are disposed in a one-to-one correspondence with the first openings, and the second dams are disposed in a one-to-one correspondence with the first dams.

In some embodiments, an interval between ends of two adjacent first dams close to the second dams is less than or equal to an interval between ends of two adjacent second dams close to the first dams.

In some embodiments, a pattern of a longitudinal section of each of the first dams is an isosceles trapezoid, the isosceles trapezoid comprises a first top edge, a first bottom edge, and two first waist edges, both of the first waist edges are connected between the first top edge and the first bottom edge and located on opposite sides of the first top edge, and a length of the first top edge is less than a length of the first bottom edge;
a pattern of a longitudinal section of each of the second dams is an isosceles inverted trapezoid comprising a second top edge, a second bottom edge, and two second waist edges, wherein both of the second waist edges are connected between the second top edge and the second bottom edge and located on opposite sides of the second top edge, and a length of the second top edge is greater than a length of the second bottom edge; and
wherein an included angle between the second top edge and each of the second waist edges is greater than or equal to an included angle between the first bottom edge and each of the first waist edges.

In some embodiments, the included angle between the second top edge and each of the second waist edges is greater than or equal to 30 degrees and less than or equal to 60 degrees.

In some embodiments, each of the plurality of light-emitting elements emits a first color light, the light-emitting substrate further comprises:
a color conversion layer comprising first color conversion units and second color conversion units; and
transparent filling units;
wherein one of the first color conversion units, one of the second color conversion units, and one of the transparent filling units are respectively filled in three adjacent second openings, the first color conversion units convert the first color light into a second color light, the second color conversion units convert the first color light into a third color light, the first color light passes through the transparent filling units, and colors of the first color light, the second color light, and the third color light are different from each other.

In some embodiments, the light-emitting substrate further comprises: a plurality of convex lenses disposed on a side of the light transmitting layer away from the substrate and corresponding to the plurality of light-emitting elements.

In some embodiments, the plurality of light-emitting elements comprise light-emitting elements emitting at least two different colors of light, and each two of the light-emitting elements emitting two different colors of light are respectively located in two adjacent first openings.

In some embodiments, the light-emitting substrate further comprises: a protective layer disposed between the plurality of convex lenses and located on the pixel definition layer.

A display device, wherein the display device comprises the above light-emitting substrate.

### Beneficial Effects of the Disclosure

### Beneficial Effects

The present disclosure provides a light-emitting substrate and a display device. The refractive index of the light transmitting layer is greater than the refractive index of a plurality of first dams, so that side light emitted by the light-emitting elements is totally reflected at interface between the first dams and the light transmitting layer, and the totally reflected light is incident on a light-emitting surface of the light-emitting substrate, thereby increasing a light extraction efficiency of the light-emitting elements on the light-emitting surface of the light-emitting substrate.

### BRIEF DESCRIPTION OF DRAWINGS

### Description of Drawings

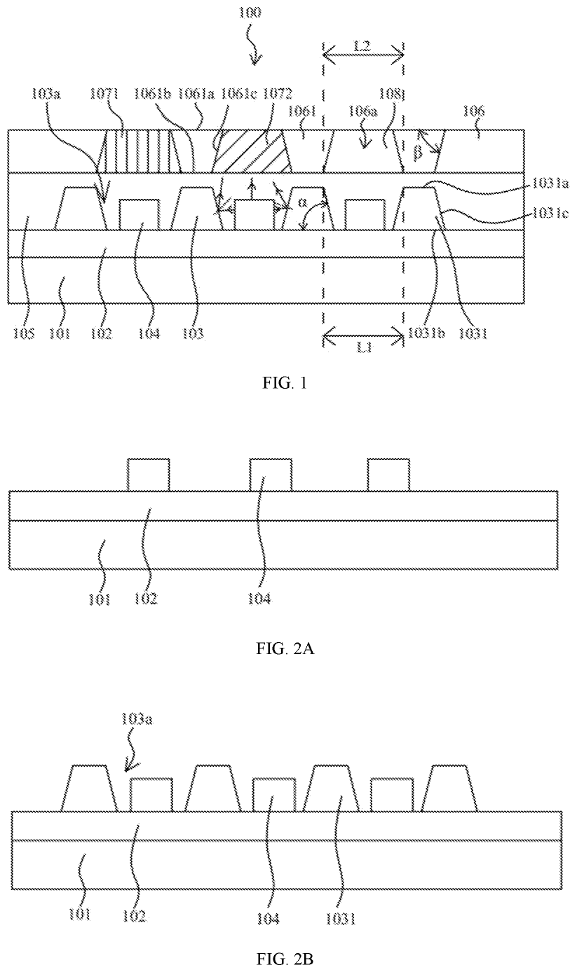

FIG. 1 is a schematic cross-sectional view of a light-emitting substrate according to a first embodiment of the present disclosure.

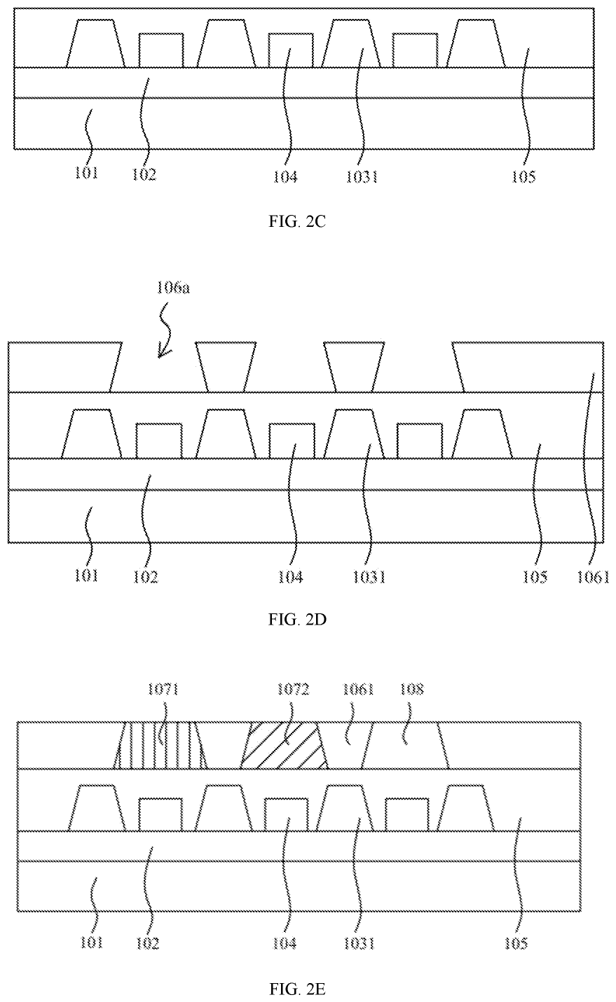

FIG. 2A-2E is a schematic diagram of a process for manufacturing the light-emitting substrate shown in FIG. 1.

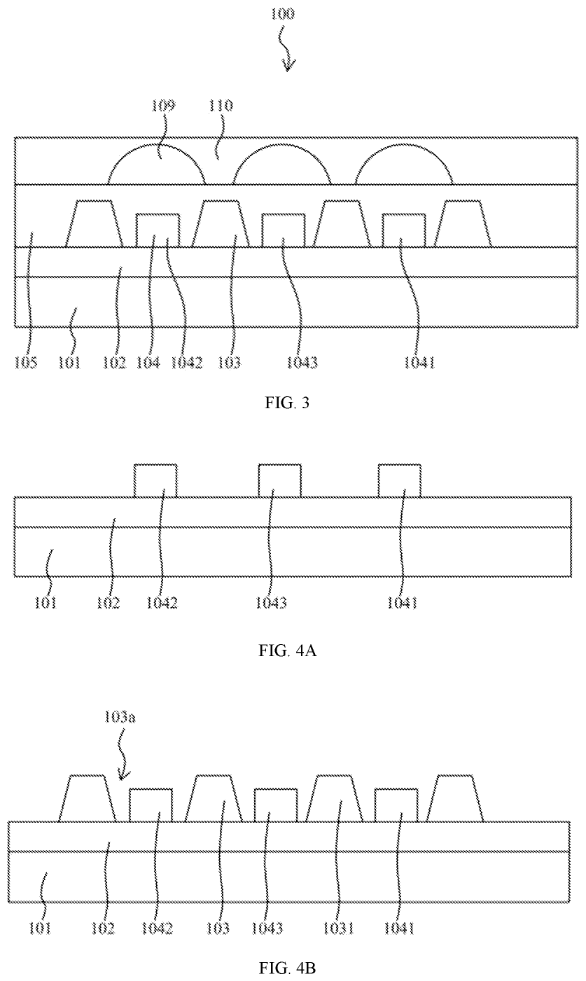

FIG. 3 is a schematic cross-sectional view of a light-emitting substrate according to a second embodiment of the present disclosure.

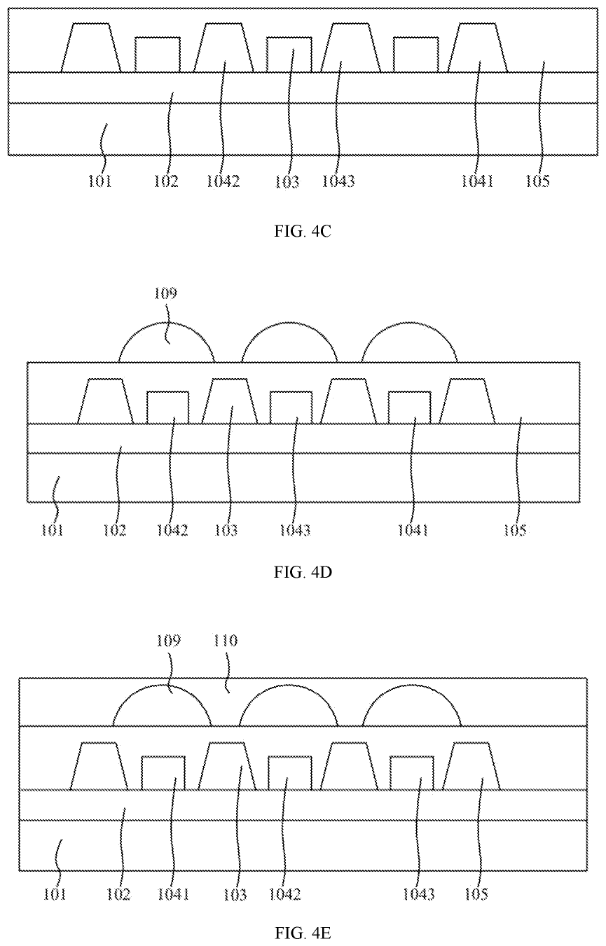

FIG. 4A-4E is a schematic diagram of a process for manufacturing the light-emitting substrate shown in FIG. 3.

### DETAILED DESCRIPTION

### Embodiments of the Disclosure

Technical solutions in embodiments of the present disclosure will be clearly and completely described below in conjunction with drawings in the embodiments of the present disclosure. Obviously, the described embodiments are only a part of embodiments of the present disclosure, rather than all the embodiments. Based on the embodiments in the present disclosure, all other embodiments obtained by those skilled in the art without creative work fall within protection scope of the present disclosure.

As shown in FIG. 1, FIG. 1 is a schematic cross-sectional view of a light-emitting substrate according to a first embodiment of the present disclosure. The light-emitting substrate 100 comprises a substrate 101, a thin film transistor array layer 102, a pixel definition layer 103, a plurality of light-emitting elements 104, and a light transmitting layer 105.

In this embodiment, the substrate 101 is a glass substrate, the thin film transistor array layer 102 is disposed on the substrate 101, and the thin film transistor array layer 102 comprises a plurality of conductive pads for bonding with the plurality of light-emitting elements 104 (not shown).

In this embodiment, the pixel definition layer 103 is opaque, the pixel definition layer 103 is configured to define a light-emitting region and prevents color mixing when colors of light emitted by two adjacent first openings 103a are different. The pixel definition layer 103 is disposed on the substrate 101. The pixel definition layer 103 comprises a plurality of first openings 103a and a plurality of first dams 1031. Sidewalls of the plurality of first dams 1031 enclose for forming the plurality of first openings 103a, and the plurality of first openings 103a expose the plurality of conductive pads of the thin film transistor array layer 102.

Specifically, the pixel definition layer 103 is disposed on the thin film transistor array layer 102. A pattern corresponding to a longitudinal section of each of the first dams 1031 is an isosceles trapezoid. The isosceles trapezoid comprises a first top edge 1031a, a first bottom edge 1031b, and two first waist edges 1031c. The two first waist edges 1031c are connected between the first top edge 1031a and the first bottom edge 1031b and are located on opposite sides of the first top edge 1031a. A length of the first top edge 1031a is less than a length of the first bottom edge 1031b. There is a first included angle α between the first bottom edge 1031b and each of the first waist edges 1031c, the first included angle α is greater than 0 degree and less than 90 degrees, for example, the first included angle is 20 degrees, 30 degrees, 40 degrees, 50 degrees, 60 degrees, or 80 degrees.

In this embodiment, the plurality of light-emitting elements 104 are located in the first openings 103a and are disposed on the substrate 101 by binding to the plurality of conductive pads. A height of the plurality of light-emitting elements 104 is less than a height of the plurality of first dams 1031 to ensure that the plurality of light-emitting elements 104 are accommodated in the plurality of first openings 103a. The light-emitting elements 104 are any one of micro light-emitting diodes or sub-millimeter light-emitting diodes. Each of the plurality of light-emitting elements 104 emits a first color light, that is, color of light emitted by the plurality of light-emitting elements 104 is same. Specifically, the light-emitting elements 104 are micro light-emitting diodes.

In this embodiment, a distance from a sidewall of each of the light-emitting elements 104 close to one of the first dams 1031 to a side wall of the first dam 1031 is 0.5 μm-1 μm, for example, 0.6 μm, 0.7 μm, or 1 μm, in order to provide enough accommodation space for the light-emitting elements 104.

In this embodiment, the light transmitting layer 105 is configured to fill gaps between the light-emitting elements 104 and the pixel definition layer 103 and to flatten a surface of the light-emitting substrate 100. The light transmitting layer 105 is at least partially filled in the plurality of first openings 103a and covers the plurality of light-emitting elements 104. The light transmitting layer 105 is transparent. Specifically, a portion of the light transmitting layer 105 is filled in the plurality of first openings 103a and covers the plurality of light-emitting elements 104, and another portion of the light transmitting layer 105 covers the plurality of first dams 1031 of the pixel definition layer 103. It can be understood that the light transmitting layer 105 may be merely filled in the plurality of first openings 103a and cover the plurality of light-emitting elements 104.

In this embodiment, a refractive index of the light transmitting layer 105 is greater than a refractive index of the plurality of first dams 1031, so that part of light emitted from side surfaces of the light-emitting elements 104 is totally reflected at interface between the first dams 1031 and the light transmitting layer 105, and the total reflected light is converged to a light-emitting surface of the light-emitting substrate 100, thereby increasing a light extraction efficiency of the light-emitting elements 104 on the light-emitting surface of the light-emitting substrate 100. Specifically, a preparation material of the pixel definition layer 103 is organic ester, and a preparation material of the light transmitting layer 105 is polyimide.

In this embodiment, the light-emitting substrate 100 further comprises a barrier layer 106, and the barrier layer 106 is opaque. The barrier layer 106 is located on a side of the light transmitting layer 105 away from the substrate 100, the barrier layer 106 comprises a plurality of second openings 106a and a plurality of second dams 1061, and sidewalls of the plurality of second dams 1061 enclose for forming the plurality of second openings 106a. The second openings 106a are set in a one-to-one correspondence with the first openings 103a, that is, one second opening 106a is positioned directly above one first opening 103a in a thickness direction of the light-emitting substrate 100, so that light emitted from the first openings 103a can be incident into the second openings 106a. The second dams 1061 are set in a one-to-one correspondence with the first dams 1031, that is, one second dam 1061 is positioned directly above one first dam 1031 in the thickness direction of the light-emitting substrate 100 to prevent color mixing between different colors of light incident in the plurality of second openings 106a, and the second dams 1061 cooperate with the first dams 1031 to further prevent color mixing between different colors of light emitted from the first openings 103a.

Specifically, a pattern of a longitudinal section of each of the second dams 1061 is an inverted isosceles trapezoid. The isosceles inverted trapezoid comprises a second top edge 1061a, a second bottom edge 1061b, and two second waist edges 1061c. The two second waist edges 1061c are connected between the second top edge 1061a and the second bottom edge 1061b and are located on opposite sides of the second top edge 1061a. A length of the second top edge 1061a is greater than a length of the second bottom edge 1061b. There is a second included angle β between the second top edge 1061a and each of the second waist edges 1061c, and the second included angle β is greater than 0 degree and less than 90 degrees, for example, the second included angle β is 20 degrees, 30 degrees, 40 degrees, 50 degrees, 60 degrees, or 80 degrees.

In this embodiment, a first interval L1 between ends of adjacent two first dams 1031 close to the second dams 1061 is less than or equal to a second interval L2 between ends of adjacent two second dams 1061 close to the first dams 1031, so as to prevent the second dams 1061 from blocking light emitted from the first openings 103a, resulting in a low light extraction efficiency of the light-emitting substrate 100.

In this embodiment, the second included angle β between the second top edge 1061a and each of the second waist edges 1061c is greater than or equal to the first included angle α between the first bottom edge 1031b and each of the first waist edges 1031c, so as to prevent blocking of light due to the second included angle β being too small, causing the light-emitting substrate to have a low light extraction efficiency.

Specifically, the second included angle β between the second top edge 1061a and each of the second waist edges 1061c is greater than or equal to 30 degrees and less than or equal to 60 degrees, so as to ensure that preparation of the second dams 1061 adapts to limitations of manufacturing process while ensuring a high light extraction efficiency of the light-emitting substrate 100.

In this embodiment, the light-emitting substrate 100 further comprises a color conversion layer including first color conversion units 1071 and second color conversion units 1072, the light-emitting substrate 100 further comprises a plurality of transparent filling units 108, and one first color conversion unit 1071, one second color conversion unit 1072, and one transparent filling unit 108 are respectively filled in three adjacent second openings 106a. The first color conversion units 1071 convert the first color light into a second color light, the second color conversion units 1072 convert the first color light into a third color light, and the first color light passes through the transparent filling units 108, and colors of the first color light, the second color light, and the third color light are different from each other. Preparation materials of the first color conversion units 1071 and the second color conversion units 1072 comprise quantum dots, and a preparation material of the transparent filling units is a transparent organic material. Specifically, one first color conversion unit 1071, one second color conversion unit 1072, and one transparent filling unit 108 are set adjacent to each other and repeated as a repeating unit. A second dam 1061 between two adjacent second openings 106a acts as a barrier to prevent color mixing. The color of the first color light emitted by the plurality of light-emitting elements 104 is blue, the color of the second color light is red, and the color of the third color light is green.

In this embodiment, the color of the first color light emitted from the light-emitting elements in the light-emitting substrate is blue, when light emitted from the side surfaces of the light-emitting elements is incident on the first dams through the light transmitting layer, the light is transmitted from an optically denser medium to an optically thinner medium since the refractive index of the light transmitting layer is greater than the refractive index of the first dams, part of the light is totally reflected at the interface between the first dams and the light transmitting layer and converges with light emitted from front surfaces of the light-emitting elements, the total reflected light and the light emitted from the front surfaces of the light-emitting elements are incident on the first color conversion units, the second color conversion units, and the transparent filling units, the first color conversion units convert the first color light into the second color light, the second color conversion units convert the first color light into the third color light, the first color light passes through the transparent filling units, and the light-emitting substrate emits the first color light, the second color light, and the third color light, so that the light extraction efficiency of the light-emitting substrate is improved while enabling the light-emitting substrate to realize color display.

The present disclosure also provides a method of manufacturing the light-emitting substrate as shown in FIG. 1. The manufacturing process of the light-emitting substrate shown in FIG. 1 comprises following steps:

In step S100, providing a substrate, and transferring light-emitting elements onto the substrate.

Specifically, a glass substrate 101 is provided, and a thin film transistor array layer 102 is formed on the glass substrate 101. The thin film transistor array layer 102 comprises a plurality of conductive pads, and after transferring a plurality of light-emitting elements 104 onto the substrate, the plurality of light-emitting elements 104 are bonded to a plurality of conductive pads, as shown in FIG. 2A.

Step S101, forming a pixel definition layer on the substrate, wherein the pixel definition layer comprises a plurality of first openings and a plurality of first dams, sidewalls of the plurality of first dams enclose for forming the plurality of first openings, and the plurality of light-emitting elements are located in the first openings.

Specifically, a pixel definition layer entirely covering the plurality of light-emitting elements 104 and the thin film transistor array layer 102 is formed, and after exposure and development, a plurality of first openings 103a exposing the plurality of light-emitting elements 104 are formed, and correspondingly, a plurality of first dams 1031 are formed, as shown in FIG. 2B.

Step S102, forming a light transmitting layer covering the pixel definition layer, the plurality of light-emitting elements, and the thin film transistor array layer.

Specifically, while gaps between the plurality of light-emitting elements 104 and the plurality of first dams 1031 are filled by coating a material of high levelness, the material of high levelness covers the plurality of first dams 1031 to form a light transmitting layer 105 having a flat surface, as shown in FIG. 2C.

Step S103, forming a barrier layer on a side of the light transmitting layer away from the substrate, wherein the barrier layer comprises a plurality of second openings and a plurality of second dams, sidewalls of the plurality of second dams enclose for forming the plurality of second openings, the second openings are set in a one-to-one correspondence with the first openings, and the second dams are set in a one-to-one correspondence with the first dams.

Specifically, after forming the entire barrier layer on a surface of the light transmitting layer 105 away from the substrate 101, a plurality of second openings 106a are obtained by exposure and development, and correspondingly, a plurality of second dams 1061 are formed, as shown in FIG. 2D.

Step S104, forming a first color conversion unit, a second color conversion unit, and a transparent filling unit respectively in each three adjacent second openings.

Specifically, the first color conversion units 1071 are formed in a plurality of second openings 106a by ink jet printing or coating, and the second color conversion units 1072 are formed in a plurality of second openings 106a adjacent to the plurality of first color conversion units 1071 by ink jet printing or coating, and finally, the transparent filling units 108 are formed in a plurality of second openings 106a adjacent to the plurality of second color conversion units 1072, as shown in FIG. 2E. One first color conversion unit 1071, one second color conversion unit 1072, and one transparent filling unit 108 adjacent to each other constitute a repeating unit.

As shown in FIG. 3, FIG. 3 is a schematic cross-sectional view of a light-emitting substrate according to a second embodiment of the present disclosure. The light-emitting substrate shown in FIG. 3 comprises a substrate 101, a thin film transistor array layer 102, a pixel definition layer 103, a plurality of light-emitting elements 104, a light transmitting layer 105, a plurality of convex lenses 109, and a protective layer 110. The substrate 101, the thin film transistor array layer 102, the pixel definition layer 103, and the light transmitting layer 105 shown in FIG. 3 are same as those in the first embodiment, and will not be described in detail here.

In this embodiment, the plurality of convex lenses 109 serve to converge light to increase the light extraction efficiency of the light-emitting substrate. The plurality of convex lenses 109 are disposed on a side of the light transmitting layer 105 away from the substrate 101 and corresponding to the plurality of light-emitting elements 104. Specifically, the plurality of convex lenses 109 are disposed on the light transmitting layer 105 and are set in a one-to-one correspondence with the plurality of light-emitting elements 104. The plurality of convex lenses 109 are transparent, and the plurality of convex lenses 109 are obtained by forming an entire organic layer and patterning the entire organic layer. A longitudinal section of the plurality of convex lenses 109 is semicircular-shaped, and a circular arc edge of the semicircular shape is located on a side of a straight line edge of the semicircular shape away from the substrate. A length of the straight line edge of the semicircular shape is greater than or equal to an interval between ends of two adjacent first dams 1031 close to the convex lenses 109, so as to ensure that light emitted from the first openings 103a can be incident on the convex lenses 109, and further improve a light extraction efficiency of the light-emitting substrate.

In this embodiment, the plurality of light-emitting elements 104 comprise light-emitting elements 104 emitting at least two different colors of light, and two light-emitting elements 104 emitting two different colors of light are respectively located in two adjacent first openings 103a. Specifically, the plurality of light-emitting elements 104 comprise first light-emitting elements 1041 that emit a first color light, second light-emitting elements 1042 that emit a second color light, and third light-emitting elements 1043 that emit a third color light, that are disposed adjacent to each other, and a color of the first color light is blue, a color of the second color light is red, and a color of the third color light is green.

In this embodiment, the protective layer 110 plays a role of protecting the plurality of convex lenses 109 and the pixel definition layer 103. The protective layer 110 is disposed between the plurality of convex lenses 109 and on the pixel definition layer 103. The protective layer 110 is transparent.

In the light-emitting substrate of this embodiment, the light-emitting elements emitting three different colors are disposed in the first openings, the pixel definition layer defines a light-emitting region and prevents color mixing between different colors of light emitted by two adjacent light-emitting elements. Since a refractive index of the light transmitting layer is greater than a refractive index of the first dams, when light emitted from side surfaces of the light-emitting elements is incident on the first dams from the light transmitting layer, the light is transmitted from an optically denser medium to an optically thinner medium, and when part of the light is totally reflected at interface between the first dams and the light transmitting layer and converged by the convex lenses, and the converged light is emitted to outside of the light-emitting substrate, so that while the light-emitting substrate achieves full color display, the light extraction efficiency of the light-emitting substrate is improved.

The present disclosure further provides a method of manufacturing the light-emitting substrate shown in FIG. 3. The manufacturing process of the light-emitting substrate shown in FIG. 3 comprises following steps:

Step S200, providing a substrate, and transferring light-emitting elements onto the substrate.

Specifically, a glass substrate 101 is provided, and a thin film transistor array layer 102 is formed on the glass substrate 101. The thin film transistor array layer 102 comprises a plurality of conductive pads, and second light-emitting elements 1042, third light-emitting elements 1043, and first light-emitting elements 1041 are sequentially transferred and bonded to the plurality of conductive pads, as shown in FIG. 4A. The first light-emitting elements 1041 emit blue light, the second light-emitting elements 1042 emit red light, and the third light-emitting elements 1043 emit green light.

Step S201, forming a pixel definition layer 103 on the substrate 101, wherein the pixel definition layer 103 comprises a plurality of first openings 103a and a plurality of first dams 1031, sidewalls of the plurality of first dams 1031 enclose for forming the plurality of first openings 103a, and a plurality of light-emitting elements 104 are located in the first openings 103a.

Specifically, the method of forming the pixel definition layer 103 in this step is same as the above-described step S101 except that one first light-emitting element 1041, one second light-emitting element 1042, and one third light-emitting element 1043 are respectively disposed in three adjacent first openings 103a, as shown in FIG. 4B.

Step S202, forming a light-transmitting layer covering the pixel definition layer, the plurality of light-emitting elements, and the thin film transistor array layer.

Specifically, this step is same as the above-described step S102, and will not be described in detail here, as shown in FIG. 4C.

In step S203, forming a plurality of convex lenses on a side of the light transmitting layer away from the substrate, and the plurality of the convex lenses are disposed corresponding to the plurality of light-emitting elements.

Specifically, after an entire light transmitting organic layer is formed on the light transmitting layer 105, the organic layer is patterned to prepare the plurality of convex lenses 109, and the plurality of convex lenses 109 are disposed in a one-to-one correspondence with the plurality of light-emitting elements 104, as shown in FIG. 4D.

Step S204, forming a protective layer covering the light transmitting layer and the plurality of convex lenses.

Specifically, an entire protective layer 110 is formed by coating, as shown in FIG. 4E.

It should be noted that the plurality of convex lenses design in the second embodiment of the present disclosure may also be applied to the first embodiment, the plurality of convex lenses are disposed on a side of the barrier layer away from the substrate and are disposed corresponding to the first color conversion units, the second color conversion units, and the transparent filling units, respectively. In addition, a barrier layer design in the first embodiment of the present disclosure may also be applied to the second embodiment. The barrier layer design is equivalent to pulling up a height of the pixel definition layer, and the barrier layer design cooperated with the pixel definition layer prevents color mixing between different colors of light emitted from the first openings.

The present disclosure further provides a display device, the display device includes any one of the above-described light-emitting substrates. When the display device is a liquid crystal display device, the display device further comprises a liquid crystal display panel, and the light-emitting substrate is disposed as a backlight on a back surface of a light-emitting surface of the liquid crystal display panel. The light-emitting substrate may be directly used as a display panel.

The descriptions of the above embodiments are only used to help understand technical solutions and core ideas of the present disclosure. Those of ordinary skilled in the art should understand that the technical solutions recorded in the foregoing embodiments can still be modified, or some technical features can be equivalently replaced; and these modifications or replacements do not cause the essence of the corresponding technical solutions to deviate from the scope of the technical solutions of the embodiments of the present disclosure.

What is claimed is:

1. A light-emitting substrate, comprising:
a substrate;
a pixel definition layer disposed on the substrate and comprising a plurality of first openings and a plurality of first dams, wherein sidewalls of the plurality of first dams enclose for forming the plurality of first openings;
a plurality of light-emitting elements located in the first openings and disposed on the substrate; and
a light transmitting layer, wherein at least a portion of the light transmitting layer fills the plurality of first openings and covers the plurality of light-emitting elements;
wherein a refractive index of the light transmitting layer is greater than a refractive index of the plurality of first dams.

2. The light-emitting substrate according to claim 1, wherein the light-emitting substrate further comprises:
a barrier layer located on a side of the light transmitting layer away from the substrate, wherein the barrier layer comprises a plurality of second openings and a plurality of second dams, sidewalls of the plurality of second dams enclose for forming the plurality of second openings, the second openings are disposed in a one-to-one correspondence with the first openings, and the second dams are disposed in a one-to-one correspondence with the first dams.

3. The light-emitting substrate according to claim 2, wherein an interval between ends of two adjacent first dams close to the second dams is less than or equal to an interval between ends of two adjacent second dams close to the first dams.

4. The light-emitting substrate according to claim 2, wherein a pattern corresponding to a longitudinal section of each of the first dams is an isosceles trapezoid, the isosceles trapezoid comprises a first top edge, a first bottom edge, and two first waist edges, both of the first waist edges are connected between the first top edge and the first bottom edge and located on opposite sides of the first top edge, and a length of the first top edge is less than a length of the first bottom edge;
a pattern of a longitudinal section corresponding to each of the second dams is an inverted isosceles trapezoid comprising a second top edge, a second bottom edge, and two second waist edges, wherein both of the second waist edges are connected between the second top edge and the second bottom edge and located on opposite sides of the second top edge, and a length of the second top edge is greater than a length of the second bottom edge; and
wherein an included angle between the second top edge and each of the second waist edges is greater than or equal to an included angle between the first bottom edge and each of the first waist edges.

5. The light-emitting substrate according to claim 4, wherein the included angle between the second top edge and each of the second waist edges is greater than or equal to 30 degrees and less than or equal to 60 degrees.

6. The light-emitting substrate according to claim 2, wherein each of the plurality of light-emitting elements emits a first color light, the light-emitting substrate further comprises:
a color conversion layer comprising first color conversion units and second color conversion units; and
transparent filling units;
wherein one of the first color conversion units, one of the second color conversion units, and one of the transparent filling units are respectively filled in three adjacent second openings, the first color conversion units convert the first color light into a second color light, the second color conversion units convert the first color light into a third color light, the first color light passes through the transparent filling units, and colors of the first color light, the second color light, and the third color light are different from each other.

7. The light-emitting substrate according to claim 1, wherein the light-emitting substrate further comprises:
a plurality of convex lenses disposed on a side of the light transmitting layer away from the substrate and corresponding to the plurality of light-emitting elements.

8. The light-emitting substrate according to claim 7, wherein the plurality of light-emitting elements comprise light-emitting elements respectively emitting at least two different colors of light, and the light-emitting elements emitting two different colors of light are respectively located in two adjacent first openings.

9. The light-emitting substrate according to claim 7, wherein the light-emitting substrate further comprises:
a protective layer disposed between the plurality of convex lenses and located on the pixel definition layer.

10. A display device, wherein the display device comprises a light-emitting substrate, and the light-emitting substrate comprises:
a substrate;
a pixel definition layer disposed on the substrate and comprising a plurality of first openings and a plurality of first dams, wherein sidewalls of the plurality of first dams enclose for forming the plurality of first openings;
a plurality of light-emitting elements located in the first openings and disposed on the substrate; and
a light transmitting layer, wherein at least a portion of the light transmitting layer fills the plurality of first openings and covers the plurality of light-emitting elements;
wherein a refractive index of the light transmitting layer is greater than a refractive index of the plurality of first dams.

11. The display device according to claim 10, wherein the light-emitting substrate further comprises:
a barrier layer located on a side of the light transmitting layer away from the substrate, wherein the barrier layer comprises a plurality of second openings and a plurality of second dams, sidewalls of the plurality of second dams enclose for forming the plurality of second openings, the second openings are disposed in a one-to-one correspondence with the first openings, and the second dams are disposed in a one-to-one correspondence with the first dams.

12. The display device according to claim 11, wherein an interval between ends of two adjacent first dams close to the second dams is less than or equal to an interval between ends of two adjacent second dams close to the first dams.

13. The display device according to claim 11, wherein a pattern corresponding to a longitudinal section of each of the first dams is an isosceles trapezoid, the isosceles trapezoid comprises a first top edge, a first bottom edge, and two first waist edges, both of the first waist edges are connected between the first top edge and the first bottom edge and located on opposite sides of the first top edge, and a length of the first top edge is less than a length of the first bottom edge;
a pattern of a longitudinal section of the second dams is an isosceles inverted trapezoid comprising a second top edge, a second bottom edge, and two second waist edges, wherein both of the second waist edges are connected between the second top edge and the second bottom edge and located on opposite sides of the second top edge, a length of the second top edge is greater than a length of the second bottom edge; and
wherein an included angle between the second top edge and each of the second waist edges is greater than or equal to an included angle between the first bottom edge and each of the first waist edges.

14. The display device according to claim 13, wherein the included angle between the second top edge and each of the second waist edges is greater than or equal to 30 degrees and less than or equal to 60 degrees.

15. The display device according to claim 11, wherein each of the plurality of light-emitting elements emits a first color light, the light-emitting substrate further comprises:
a color conversion layer comprising first color conversion units and second color conversion units; and
transparent filling units;
wherein one of the first color conversion units, one of the second color conversion units, and one of the transparent filling units are respectively filled in three adjacent second openings, the first color conversion units convert the first color light into a second color light, the second color conversion units convert the first color light into a third color light, the first color light passes through the transparent filling units, and colors of the first color light, the second color light, and the third color light are different from each other.

16. The display device according to claim 10, wherein the light-emitting substrate further comprises:
a plurality of convex lenses disposed on a side of the light transmitting layer away from the substrate and corresponding to the plurality of light-emitting elements.

17. The display device according to claim 16, wherein the plurality of light-emitting elements comprise light-emitting elements respectively emitting at least two different colors of light, and each two of the light-emitting elements emitting two different colors of light are respectively located in two adjacent first openings.

18. The display device according to claim 16, wherein the light-emitting substrate further comprises:
a protective layer disposed between the plurality of convex lenses and located on the pixel definition layer.
